(19) United States
(12) Patent Application Publication
(10) Pub. No.: US 2018/0183441 A1
(43) Pub. Date: Jun. 28, 2018

(54) FREQUENCY DIVIDER

(71) Applicant: KOREA ADVANCED INSTITUTE OF SCIENCE AND TECHNOLOGY, Daejeon (KR)

(72) Inventors: Seung Tak RYU, Daejeon (KR); Si Nai KIM, Daejeon (KR)

(73) Assignee: KOREA ADVANCED INSTITUTE OF SCIENCE AND TECHNOLOGY, Daejeon (KR)

(21) Appl. No.: 15/406,016

(22) Filed: Jan. 13, 2017

(30) Foreign Application Priority Data
Dec. 28, 2016 (KR) 10-2016-0181192

(51) Int. Cl. H03K 21/08; H03K 3/356; H03K 19/20

(52) U.S. Cl. CPC H03K 21/08; H03K 19/20; H03K 3/356

(57) ABSTRACT

A frequency divider is provided. Some embodiments of the present disclosure provide a CMOS logic-based high speed differential divider that is capable of acquiring a desired output swing voltage even at low supply voltages and is robust to clock skew and clock feedthrough, featuring low power consumption.

### CROSS-REFERENCE TO RELATED APPLICATIONS

The present application is based on, and claims priority from, Korean Patent Application Number 10-2016-0181192, filed Dec. 28, 2016, the disclosure of which is incorporated by reference herein in its entirety.

### TECHNICAL FIELD

The present disclosure relates generally to frequency dividers, and more specifically to high speed differential, quadrature frequency dividers.

### BACKGROUND

The statements in this section merely provide background information related to the present disclosure and do not necessarily constitute prior art.

A semiconductor integrated circuit that operates synchronously with system clock requires clock signals of various frequencies. Instead of the entire clock signals of various frequencies being supplied externally, a frequency divider can generate clock signals of desired frequencies by dividing an introduced clock signal.

Frequency dividers based on CML DFF (Current Mode Logic D Flip Flop) are known to be robust against power supply noise, but they suffer from the difficulty to generate a required output swing voltage with lowered power supply voltage due to scaling down of device dimensions involved in the semiconductor process. Specifically, generating a required output swing voltage has become difficult while biasing the stacked transistors to operate in saturated regions.

In order to solve such difficulties, researches have been actively conducted on a high-speed differential frequency divider using CMOS logic. Of the conventional CMOS logic-based high-speed differential frequency dividers, a divider has a serial multistage configuration with inverters connected in series. Such frequency divider structure is very vulnerable to clock skew because it sequentially obtains differential signals from the outputs of inverters connected in series. Specifically, the conventional structure that requires multiple stages of inverters to obtain a differential signal is sensitive to changes in transmission delays through the inverters of the inverter chain due to changes in process, voltage, and temperature (PVT). This increases the likelihood that skew will occur between divided clock signals.

Further, the above-described conventional frequency divider structure is greatly influenced by clock feedthrough, which generates substantial voltage ripples in a divided signal. Additional inverters in between the series-connected inverter stages might take advantage of the noise margin of the inverters in an attempt to alleviate the effect of the clock feedthrough, yet more inverters will cause a substantial increase in the dynamic current consumption.

### SUMMARY

In accordance with some embodiments, the present disclosure provides a frequency divider including a first latch and a second latch. The first latch is configured to generate, based on a first input signal and a first clock signal, a first output signal transitioned from a level of the first input signal at a first edge of the first clock signal at a first output terminal, to generate, based on a second input signal, a second output signal transitioned from a level of the second input signal at the first edge of the first clock signal at a second output terminal, and to maintain levels of the first output signal and the second output signal at a second edge of the first clock signal. The second latch is configured to output, based on a signal of the first output terminal, a first feedback signal transitioned from a level of the signal of the first output terminal and feed back the first feedback signal as the second input signal at the second edge of the first clock signal, to output, based on a signal of the second output terminal, a second feedback signal transitioned from a level of the second output terminal and feed back the second feedback signal as the first input signal at the second edge of the first clock signal, and to maintain levels of the first feedback signal and the second feedback signal at the first edge of the first clock signal.

In accordance with some embodiments, the frequency divider may further include a first sub-latch which includes a first inverting unit configured to generate an inverted signal of the first input signal and output the inverted signal as the second input signal, and a second inverting unit configured to generate an inverted signal of the

In accordance with some embodiments, the frequency divider may further include a second sub-latch which includes a third inverting unit configured to generate an inverted signal of the signal of the first output terminal and output the inverted signal as the signal of the second output terminal, and a fourth inverting unit configured to generate an inverted signal of the signal of the second output terminal and output the inverted signal as the signal of the first output terminal.

### BRIEF DESCRIPTION OF THE DRAWINGS

FIG. 1 is a circuit diagram of a frequency divider according to at least one embodiment of the present disclosure.

FIG. 2 is a schematic waveform diagram of a frequency divider according to at least one embodiment of the present disclosure.

FIG. 3 is a circuit diagram of a frequency divider according to another embodiment of the present disclosure.

FIG. 4 is a circuit diagram of an exemplary sub-latch according to at least one embodiment of the present disclosure.

FIG. 5 is a diagram of the simulated result of a frequency divider according to at least one embodiment of the present disclosure.

### REFERENCE NUMERALS

110, 300: Frequency divider
110, 310: First latch
120, 320: Second latch
112, 312: First inverter
114, 314: Second inverter
122, 322: Third inverter
124, 324: Fourth inverter
330: First sub-latch
340: Second sub-latch

### DETAILED DESCRIPTION

According to some embodiments of the present disclosure, a CMOS logic-based high speed differential frequency divider is provided that is capable of acquiring a desired output swing voltage even at low supply voltages and is robust against clock skew and clock feedthrough while consuming less power.

Exemplary embodiments of the present disclosure are described below with reference to the accompanying drawings. In the following description, like reference numerals designate like elements, although the elements are shown in different drawings. Further, in the following description of the at least one embodiment, a detailed description of known functions and configurations incorporated herein will be omitted for the purpose of clarity and for brevity.

Additionally, various terms such as first, second, A, B, (a), (b), etc., are used solely for the purpose of differentiating one component from the other, but not to imply or suggest the substances, the order or sequence of the components. Throughout this specification, when a part “includes” or “comprises” a component, the part is meant to further include other components, not excluding thereof unless there is a particular description contrary thereto. The terms such as “unit”, “module”, and the like refer to units for processing at least one function or operation, which may be implemented by hardware, software, or a combination thereof.

The following detailed description, together with the accompanying drawings, is intended to illustrate exemplary embodiments of the present disclosure and is not intended to represent the only embodiments in which the present disclosure may be practiced.

Embodiments of the present disclosure propose a CMOS logic-based high speed differential divider that is capable of acquiring a desired output swing voltage even at low supply voltages and is robust against clock skew and clock feedthrough while consuming low power.

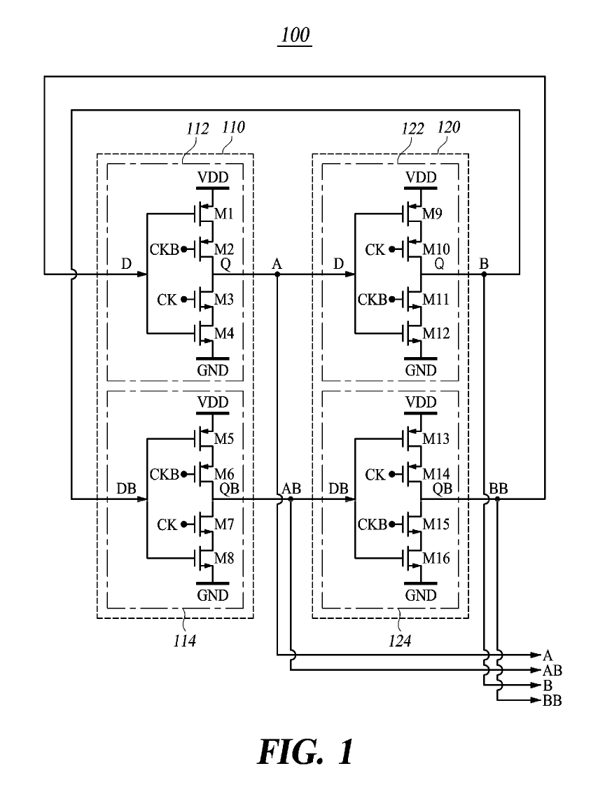

FIG. 1 is a circuit diagram of a frequency divider according to at least one embodiment of the present disclosure.

A frequency divider 100 according to at least one embodiment of the present disclosure may perform a divide-by-2 operation on the frequencies of clock signals CK and CKB input from the outside to generate frequency-divided signals A, AB, B, and BB. Here, the frequency-divided signals A and AB have a phase difference of 90 degrees from the frequency-divided signals B and BB.

Referring to FIG. 1, the frequency divider 100 includes a first latch 110 and a second latch 120. The output terminals Q and QB of the first latch 110 are connected to the input terminals D and DB of the second latch 120 respectively, and the output terminals Q and QB of the second latch 120 are inversely connected to the input terminals D and DB of the second latch 110, respectively.

The first latch 110 generates a first output signal A, transitioned from the level of a first input signal BB, to the first output terminal Q at a first edge of a first clock signal CK, in response to first input signal BB, second input signal B and first clock signal CK.

The first latch 110 generates a second output signal AB, transitioned from the level of a second input signal B, to the second output terminal QB at the first edge of first clock signal CK, in response to first input signal BB, second input signal B and first clock signal CK. For the purpose of this embodiment, the first edge refers to a rising edge.

The first latch 110 maintains the levels of first and second output signals A and AB at the second edge of first clock signal CK, in response to the first input signal BB, the second input signal B and the first clock signal CK. For the purpose of this embodiment, the second edge refers to a falling edge.

The second latch 120 outputs a first feedback signal, transitioned from the signal level of first output terminal Q of the first latch 110, at the second edge of first clock signal CK, in response to the signals of the first output terminal Q and the second output terminal QB of the first latch 110 and first clock signal CK. The first feedback signal is fed back as second input signal B of the first latch 110.

The second latch 120 outputs a second feedback signal, transitioned from the signal level of the second output terminal QB of the first latch 110, at the second edge of first clock signal CK, in response to the signals of the first output terminal Q and the second output terminal QB of the first latch 110 and first clock signal CK. The second feedback signal is fed back as first input signal BB of the first latch 110.

The second latch 120 maintains the levels of the first and second feedback signals at the first edge of the first clock signal CK, in response to the signals of the first output terminal Q and the second output terminal QB of the first latch 110 and first clock signal CK.

Each of the first latch 110 and the second latch 120 includes two stages of tri-state inverters. Specifically, the first latch 110 may include a first inverter 112 and a second inverter 114, and the second latch 110 may include a third inverter 122 and a fourth inverter 124. Hereinafter, the first to fourth inverters will be described.

The first inverter 112 includes a plurality of transistors connected in a cascode form between a power supply terminal VDD and a ground terminal GND. One of second feedback signal BB, first clock signal CK and second clock signal CKB, which is in antiphase relationship with first clock signal CK, is applied to each of the gates of the plurality of transistors of the first inverter 112.

The plurality of transistors of the first inverter 112 may include a first transistor M1, a second transistor M2, a third transistor M3 and a fourth transistor M4, which are sequentially connected from the power supply terminal VDD. Second feedback signal BB is input to the gates of the first and fourth transistors M1 and M4, second clock signal CKB is input to the gate of the second transistor M2, and first clock signal CK is input to the gate of the third transistor M3. The first and second transistors M1 and M2 are appropriately PMOS transistors and the third and fourth transistors M3 and M4 are appropriately NMOS transistors.

The second inverter 114 includes a plurality of transistors connected in a cascode form between the power supply terminal VDD and the ground terminal GND. One of first feedback signal B, first clock signal CK and second clock signal CKB is applied to each of the gates of the plurality of transistors of the second inverter 114, respectively.

The plurality of transistors of the second inverter 114 may include a fifth transistor M5, a sixth transistor M6, a seventh transistor M7 and an eighth transistor M8, which are sequentially connected from the power supply terminal VDD. First feedback signal B is input to the gates of the fifth and eighth transistors M5 and M8, second clock signal CKB is input to the gate of the sixth transistor M6, and first clock signal CK is input to the gate of the seventh transistor M7. The fifth and sixth transistors M5 and M6 are appropriately PMOS transistors and the seventh and eighth transistors M7 and M8 are appropriately NMOS transistors.

The third inverter 122 may include a plurality of transistors connected in a cascode form between the power supply terminal VDD and the ground terminal GND. One of the signal of the first output terminal Q of the first latch 110, first clock signal CK and second clock signal CKB is applied to each of the gates of the plurality of transistors of the third inverter 122.

The plurality of transistors of the third inverter 122 may include a ninth transistor M9, a tenth transistor M10, an eleventh transistor M11 and a twelfth transistor M12, which are sequentially connected from the power supply terminal VDD. The signal of the first output terminal Q of the first latch 110 is input to the gates of the ninth and twelfth transistors M9 and M12, first clock signal CK is input to the gate of the tenth transistor M10, and second clock signal CKB is input to the gate of the eleventh transistor M11. The the ninth and tenth transistors M9 and M10 are appropriately PMOS transistors and the eleventh and twelfth transistors M11 and M12 are appropriately NMOS transistors.

The fourth inverter 124 includes a plurality of transistors connected in a cascode form between the power supply terminal VDD and the ground terminal GND. One of the signal of the second output terminal QB of the first latch 110, first clock signal CK and second clock signal CKB is applied to each of the gates of the plurality of transistors of the fourth inverter 124.

The plurality of transistors of the fourth inverter 124 may include a thirteenth transistor M13, a fourteenth transistor M14, a fifteenth transistor M15 and a sixteenth transistor M16, which are sequentially connected from the power supply terminal VDD. The signal of the second output terminal QB of the first latch 110 is input to the gates of the thirteenth and sixteenth transistors M13 and M16, the first clock signal CK is input to the gate of the fourteenth transistor M14, and the second clock signal CKB is input to the gate of the fifteenth transistor M15. The thirteenth and fourteenth transistors M13 and M14 are appropriately PMOS transistors and the fifteenth and sixteenth transistors M15 and M16 are appropriately NMOS transistors.

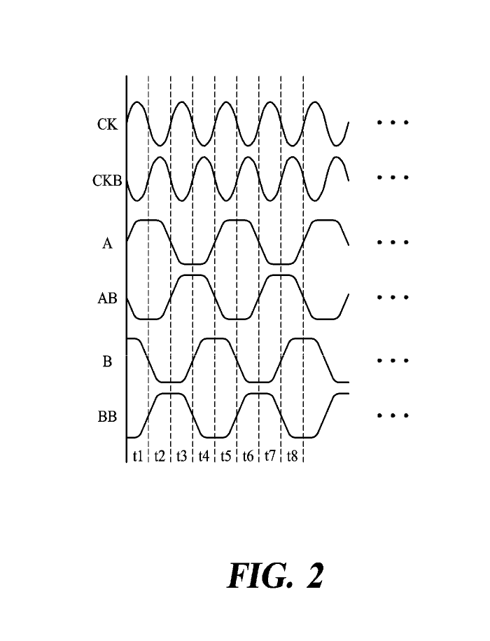

Hereinafter, the operation of a frequency divider according to at least one embodiment of the present disclosure will be described with reference to Table 1. FIG. 2 is a schematic waveform diagram of a frequency divider according to at least one embodiment of the present disclosure. Table 1 is a state table of a frequency divider according to at least one embodiment of the present disclosure. FIG. 2 and Table 1 illustrate a case where an initial input signal D of the first latch 110 is a low-level signal and an initial input signal DB is a high-level.

TABLE 1

| cycle | CK | CKB | A | AB | B | BB |
|---|---|---|---|---|---|---|
| t1 | H | L | H | L | H | L |
| t2 | L | H | H | L | L | H |
| t3 | H | L | L | H | L | H |
| t4 | L | H | L | H | H | L |
| t5 | H | L | H | L | H | L |
| t6 | L | H | H | L | L | H |
| t7 | H | L | L | H | L | H |
| t8 | L | H | L | H | H | L |

Table 1 shows logic levels of the divided signals A, AB, B, and BB output by the frequency divider of this embodiment, in response to first clock signal CK and second clock signal CKB in respective time periods (t1 to t8). Here, H denotes a high level (or logic level ‘1’), and L denotes a low level (or logic level ‘0’). Divided signal A denotes the output signal of the first inverter 112, and AB denotes the output signal of the second inverter 114. B denotes the output signal of the third inverter 122, and BB denotes the output signal of the fourth inverter 124.

During period t1, when first clock signal CK is in the rising edge state and second clock signal CKB is in the falling edge state, the first latch 110 transitions the levels of the initial input signals to output signals. Specifically, the first inverter 112 outputs a high-level signal A transitioned from the level (low level) of the initial input signal D. The second inverter 114 outputs a low-level signal AB transitioned from the level (high level) of the initial input signal DB. On the other hand, the second latch 120 maintains the original levels of output signals B and BB.

During t2, when first clock signal CK is in the falling edge state and second clock signal CKB is in the rising edge state, the second latch 120 transitions the levels of the input signals A and AB to output the signals. Specifically, the third inverter 122 outputs signal B transitioned from the high level to the low level, and the fourth inverter 124 outputs signal BB transitioned from the low level to the high level. On the other hand, the first latch 110 maintains the levels of the previous output signals A and AB.

During t3, when first clock signal CK is in the rising edge state and second clock signal CKB is in the falling edge state, the first latch 110 transitions the levels of input signals B and BB to output the signals. Specifically, the first inverter 112 outputs a signal A transitioned from the high level to the low level, and the second inverter 114 outputs a signal AB transitioned from the low level to the high level. On the other hand, the second latch 120 maintains the levels of the previous output signals B and BB.

During t4, when first clock signal CK is in the falling edge state and second clock signal CKB is in the rising edge state, the second latch 120 transitions the levels of input signals A and AB to output the signals. Specifically, the third inverter 122 outputs signal B transitioned from the low level to the high level, and the fourth inverter 124 outputs signal BB transitioned from the high level to the low level. On the other hand, the first latch 110 maintains the levels of the previous output signals A and AB.

The operation of the frequency divider of this embodiment during t5 to t8 is the same as the operation during t1 to t4 described above, and continues to be repeated thereafter. The schematic waveform according to the operation of the frequency divider described with reference to Table 2 is shown in FIG. 2. Referring to FIG. 2, the frequency of clock signals CK, CKB are processed through a divide-by-2 operation to generate divided signals A, AB and B, BB having a 90-degree phase difference therebetween.

That is, first output signal A of the first latch 110 and first feedback signal B of the second latch 120 are obtained by performing the divide-by-2 operation on the frequency of first clock signal CK and have a 90-degree phase difference therebetween. Second output signal AB of the first latch 110 and second feedback signal BB of the second latch 120 are obtained by performing the divide-by-2 operation on the frequency of second clock signal CK and have a 90-degree phase difference therebetween.

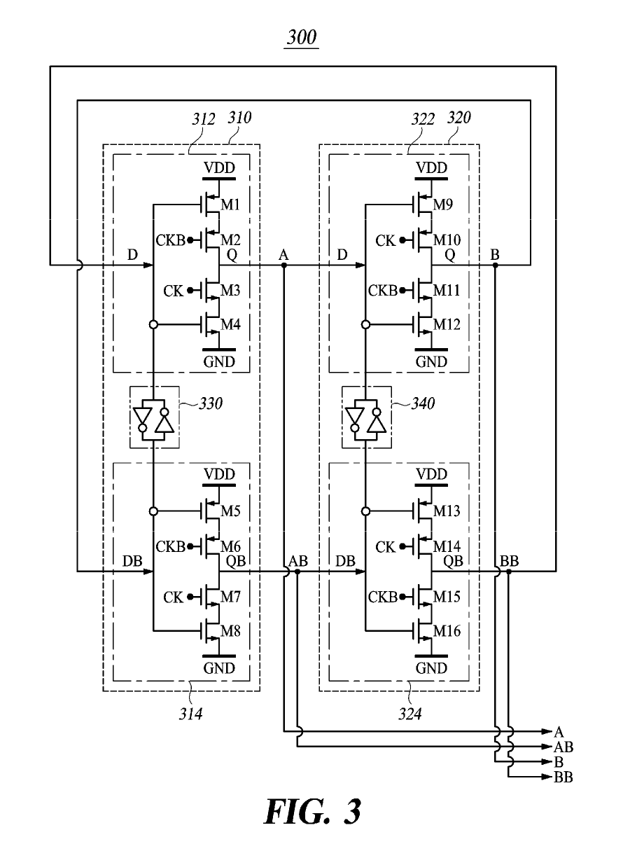

In order for the frequency divider 100 described with reference to FIG. 1 to perform the operations described with reference to FIGS. 2 and 3, different initial values need to be input to the input terminals D and DB of the latches 110 and 120. In other words, if an input signal having the same value is applied to the input terminals D and DB of the latches 110 and 120, the above-described operations may not be performed.

For example, when an initial value of high level is applied to both the input terminals D and DB of the first latch 110, the first latch 110 outputs signals A and AB, transitioned from the high level to the low level, during the period t1. During t2, the second latch 120 outputs signals B and BB transitioned from the levels of signals A and AB input from the first latch 110 to the high level. The levels of the output signals of the second latch 120 are equal to the initial input value of the first latch 110, and thus the logic levels of the first and second latches 110 and 120 remain unchanged.

Therefore, signals of different levels need to be input between the input terminals D and DB of at least one of the first latch 110 and the second latch 120. For example, desired frequency-divided signals may be obtained provided a high-level signal is input to the input terminal D and a low-level signal is input to the input terminal DB and vice versa.

The frequency divider according to another embodiment of the present disclosure may further include a sub-latch configured to generate input values of different levels for the input terminals D and DB of at least one latch of the first latch and the second latch. Hereinafter, this configuration will be described in detail with reference to FIG. 3.

FIG. 3 is a circuit diagram of a frequency divider according to another embodiment of the present disclosure.

Referring to FIG. 3, a frequency divider 300 according to this embodiment includes a first latch 310 and a second latch 320. The operations of the first latch 310 and the second latch 320 are the same as those described above with reference to FIGS. 2 and 3, and a detailed description thereof will be omitted.

The first latch 310 may include a first sub-latch 330 to generate input values of different levels for each of the input terminals D and DB. The first sub-latch 330 is connected between the input terminals D and DB of the first latch 310. The first sub-latch 330 does not allow an input signal of the same level to be applied to the input terminals D and DB of the first latch 310.

More specifically, the first sub-latch 330 may generate an inverted signal of the first input signal D of the first latch 310 and output the same as a second input signal DB of the first latch 310. In contrast, the first sub-latch 330 may generate an inverted signal of the second input signal DB and output the same as a first input signal D.

The second latch 320 may also include a second sub-latch 340 to generate input values of different levels for each of the input terminals D and DB. The second sub-latch 340 is connected between the input terminals D and DB of the second latch 320. The second sub-latch 340 does not allow an input signal of the same level to be applied to the input terminals D and DB of the second latch 320.

More specifically, the second sub-latch 340 may generate an inverted signal of the signal of the first output terminal Q of the first latch 310 and output the same as a signal of a second output terminal QB. In contrast, the second sub-latch 340 may generate an inverted signal of the signal of the second output terminal QB and output the same as a signal of the first output terminal Q.

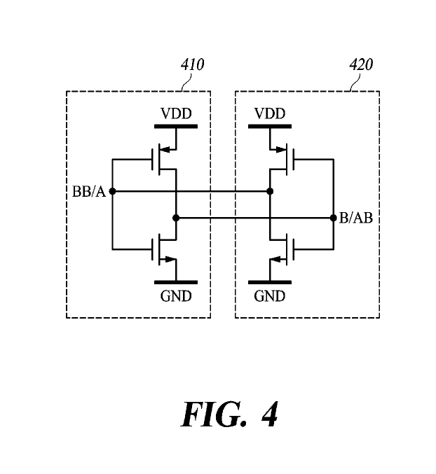

FIG. 4 is a circuit diagram of an exemplary sub-latch according to at least one embodiment of the present disclosure.

The following description assumes that the sub-latch of FIG. 4 is the first sub-latch 330. The first sub-latch 330 may include a first inverting unit 410 configured to generate an inverted signal of the first input signal D/BB of the first latch 310 and output the same as a second input signal DB/B of the first latch 310, and a second inverting unit 420 configured to generate an inverted signal of the second input signal DB/B and output the same as a first input signal D/BB.

Each of the first inverting unit 410 and the second inverting unit 420 may include transistors connected in the form of a cascode between the power supply terminal VDD and the ground terminal GND. The drains of the transistors included in the first inverting unit 410 may be connected to the gates of the transistors included in the second inverting unit 420. The gates of the transistors included in the first inverting unit 410 may be connected to the drains of the transistors included in the second inverting unit 420.

The following description assumes that the sub-latch of FIG. 4 is the second sub-latch 340. The second sub-latch 340 may include a third inverting unit 410 configured to generate an inverted signal of the signal A at the first output terminal Q of the first latch 310 and output the same as signal AB of the second output terminal QB of the first latch 310, and a fourth inverting unit 420 configured to generate an inverted signal of the signal AB of the second output terminal QB and output the same as signal A of the first output terminal Q.

Each of the third inverting unit 410 and the fourth inverting unit 420 may include transistors connected in the form of a cascode between the power supply terminal VDD and the ground terminal GND. The drains of the transistors included in the third inverting unit 410 may be connected to the gates of the transistors included in the fourth inverting unit 420. The gates of the transistors included in the third inverting unit 410 may be connected to the drains of the transistors included in the fourth inverting unit 420.

The first sub-latch 330 and the second sub-latch 340 may generate an initial value of the input during the initial operation of the frequency divider 300 and then perform a positive feedback operation during data shifts of the first latch 310 and the second latch 320. This suppresses voltage ripples that may occur due to clock feedthrough at the outputs of the first latch 310 and the second latch 320.

The channel widths of the transistors included in the first sub-latch 330 and the second sub-latch 340 are smaller than the channel width of the transistors included in the first to fourth inverters 312, 314, 322 and 324.

However, if the channel width of the transistors included in the first and second sub-latches 330 and 340 is far smaller than the channel width of the transistors included in the first to fourth inverters 312, 314, 322 and 324, current may not be charged/discharged by a sufficient amount to generate an initial value of input during a period when a clock signal is not supplied. This causes the frequency divider 300 to fail to produce a required output swing voltage. Therefore, the channel width of the transistors included in the first and second sub-latches 330 and 340 needs to be large enough to produce the required output swing voltage.

In contrast, if the channel widths of the transistors included in the first and second sub-latches 330 and 340 become similar to that of the transistors included in the first to fourth inverters 312, 314, 322, and 324, the output signals A, AB, B and BB of the frequency divider 300 are distorted due to the strong positive feedback operation of the first and second sub-latches 330 and 340. Thus, the channel width of the transistors included in the first and second sub-latches 330 and 340 needs to be small enough not to affect the data transition of the first to fourth inverters 312, 314, 322 and 324.

That is, the channel width of the transistors included in the first and second sub-latches 330 and 340 may be determined in consideration of the output swing voltage of the frequency divider 300 and the degree of distortion of the output signal. Specifically, the channel width should be small enough not to affect the data transition of the frequency divider 300, but large enough to obtain the required output swing voltage. Since the channel width of the transistors included in the first sub-latch 330 and the second sub-latch 340 only needs to be sufficiently large to acquire the required output swing voltage, power consumption is not large.

For example, when in-phase and quadrature-phase signals of 5 GHz are generated by applying a 10 GHz clock signal to the frequency divider 300, the channel width of the transistors included in the first and second sub-latches 330 and 340 is appropriately within 10% to 30% of the channel width of the transistors included in the first to fourth inverters 312, 314, 322 and 324.

While FIG. 3 illustrates that the first latch 310 and the second latch 320 of the frequency divider 300 include the sub-latches 330 and 340, respectively, the present disclosure is not limited thereto. That is, only the first latch 310 may include the first sub-latch 330, or only the second latch 320 may include the second sub-latch 340.

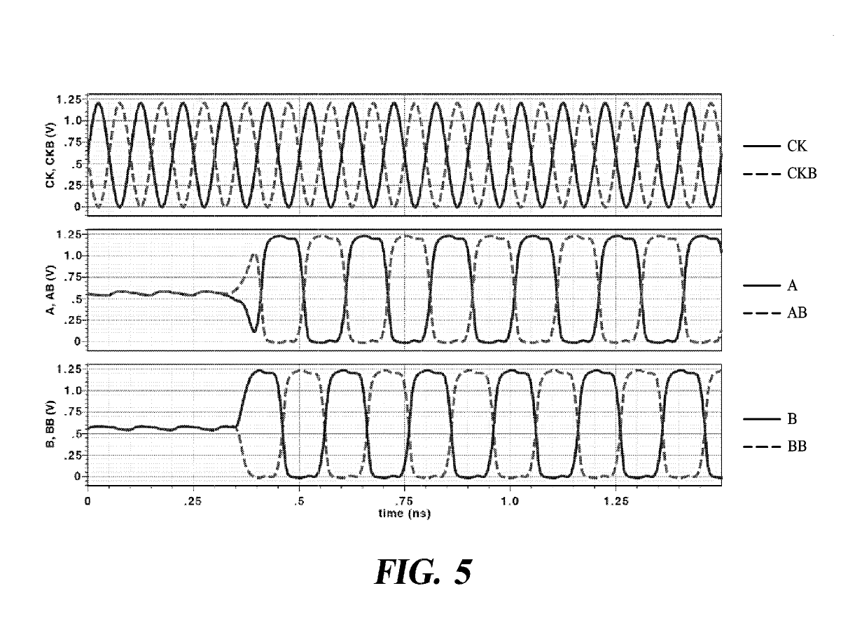

FIG. 5 is a diagram of the simulated result of a frequency divider according to at least one embodiment of the present disclosure.

Specifically, FIG. 5 shows a simulation result of processing an external 10 GHz input clock signal through a divide-by-2 operation and generating differential output signals A and AB, B and BB having a phase difference of 90 degrees. After 3.5 cycles of the external 10 GHz input clock signal CK, the second sub-latch 340 of the second latch 120 operates to cause the node A to transition to the low level and the node AB to transition to a higher level. Thereafter, the nodes A and AB output divided signals obtained by performing a divide-by-2 operation on the clock signal CK each time the clock signal CK becomes high level (i.e., every rising edge). Each time the clock signal CK becomes low level (i.e., every falling edge), the nodes B and BB output a divided signal which is delayed by 90 degrees from the phase of the nodes A and AB as a clock signal CK obtained through the divide-by-2 operation.

As described above, according to some embodiments of the present disclosure, by using a latch structure in which tri-state inverters are arranged in parallel and a sub-latch structure connected to an input terminal of a latch, a desired output swing voltage can be acquired even at a low supply voltage, achieving robustness against clock skew and clock feedthrough while maintaining low power consumption.

Although exemplary embodiments of the present disclosure have been described for illustrative purposes, those skilled in the art will appreciate that various modifications, additions and substitutions are possible, without departing from the various characteristics of the disclosure. Therefore, exemplary embodiments of the present disclosure have been described for the sake of brevity and clarity, and those embodiments are not representative of technical limitations to the idea of the present disclosure. Accordingly, one of ordinary skill would understand the scope of the disclosure is not limited by the explicitly described above embodiments but by the claims and equivalents thereof.

What is claimed is:

1. A frequency divider, comprising:
a first latch configured to
generate, based on a first input signal and a first clock signal, a first output signal transitioned from a level of the first input signal at a first edge of the first clock signal at a first output terminal,
generate, based on a second input signal, a second output signal transitioned from a level of the second input signal at the first edge of the first clock signal at a second output terminal, and
maintain levels of the first output signal and the second output signal at a second edge of the first clock signal; and
a second latch configured to
output, based on a signal of the first output terminal, a first feedback signal transitioned from a level of the signal of the first output terminal and feed back the first feedback signal as the second input signal at the second edge of the first clock signal,
output, based on a signal of the second output terminal, a second feedback signal transitioned from a level of the second output terminal and feed back the second feedback signal as the first input signal at the second edge of the first clock signal, and
maintain levels of the first feedback signal and the second feedback signal at the first edge of the first clock signal.

2. The frequency divider of claim 1, wherein the first latch comprises a first inverter and a second inverter,
wherein the first inverter comprises a plurality of transistors connected in a cascode form between a power supply terminal and a ground terminal and having respective gates each receiving one of the second feedback signal, the first clock signal, and a second clock signal in antiphase relationship with respect to the first clock signal,
wherein the second inverter comprises a plurality of transistors connected in a cascode form between the power supply terminal and the ground terminal having respective gates each receiving one of the first feedback signal, the first clock signal and the second clock signal.

3. The frequency divider of claim 2, wherein the plurality of transistors of the first inverter comprises a first transistor, a second transistor, a third transistor and a fourth transistor sequentially connected from the power supply terminal,
wherein the second feedback signal is input to the gates of the first transistor and the fourth transistor, the second clock signal is input to the gate of the second transistor, the first clock signal is input to the gate of the third transistor, and the signal of the first output terminal is output from a junction terminal between the second transistor and the third transistor.

4. The frequency divider of claim 2, wherein the plurality of transistors of the second inverter comprises a fifth transistor, a sixth transistor, a seventh transistor and an eighth transistor sequentially connected from the power supply terminal,
wherein the first feedback signal is input to the gates of the fifth transistor and the eighth transistor, the second clock signal is input to the gate of the sixth transistor, the first clock signal is input to the gate of the seventh transistor, and the signal of the second output terminal is output from a junction terminal between the sixth transistor and the seventh transistor.

5. The frequency divider of claim 1, wherein the second latch comprises a third inverter and a fourth inverter,
wherein the third inverter comprises a plurality of transistors connected in a cascode form between a power supply terminal and a ground terminal and having respective gates each receiving one of the signal of the first output terminal, the first clock signal, and a second clock signal in antiphase relationship with respect to the first clock signal,
wherein the fourth inverter comprises a plurality of transistors connected in a cascode form between the power supply terminal and the ground terminal and having respective gates each receiving one of the signal of the second output terminal, the first clock signal and the second clock signal.

6. The frequency divider of claim 5, wherein the plurality of transistors of the third inverter comprises a ninth transistor, a tenth transistor, an eleventh transistor and a twelfth transistor sequentially connected from the power supply terminal,
wherein the signal of the first output terminal is input to the gates of the ninth transistor and the twelfth transistor, the first clock signal is input to the gate of the tenth transistor, the second clock signal is input to the gate of the eleventh transistor, and the first feedback signal is output from a junction terminal between the tenth transistor and the eleventh transistor.

7. The frequency divider of claim 5, wherein the plurality of transistors of the fourth inverter comprises a thirteenth transistor, a fourteenth transistor, a fifteenth transistor and a sixteenth transistor sequentially connected from the power supply terminal,
wherein the signal of the second output terminal is input to the gates of the thirteenth transistor and the sixteenth transistor, the first clock signal is input to the gate of the fourteenth transistor, the second clock signal is input to the gate of the fifteenth transistor, and the second feedback signal is output from a junction terminal between the fourteenth transistor and the fifteenth transistor.

8. The frequency divider of claim 1, further comprising a first sub-latch comprising:
a first inverting unit configured to generate an inverted signal of the first input signal and output the inverted signal as the second input signal; and
a second inverting unit configured to generate an inverted signal of the second input signal and output the inverted signal as the first input signal.

9. The frequency divider of claim 8, wherein the first sub-latch comprises transistors having channel widths which are determined based on output swing voltages of the frequency divider and a degree of distortion of output signals.

10. The frequency divider of claim 1, further comprising a second sub-latch comprising:
a third inverting unit configured to generate an inverted signal of the signal of the first output terminal and output the inverted signal as the signal of the second output terminal; and
a fourth inverting unit configured to generate an inverted signal of the signal of the second output terminal and output the inverted signal as the signal of the first output terminal.

11. The frequency divider of claim 10, wherein the second sub-latch comprises transistors having channel widths which are determined based on output swing voltages of the frequency divider and a degree of distortion of output signals.

12. The frequency divider of claim 1, wherein the first edge is a rising edge and the second edge is a falling edge.
